(19) United States
(12) Patent Application Publication
(10) Pub. No.: US 2011/0227794 A1
(43) Pub. Date: Sep. 22, 2011

(54) PACKAGE INVERTED F-ANTENNA

(75) Inventor: Roger Fratti, Mohnton, PA (US)

(73) Assignee: LSI Corporation

(21) Appl. No.: 12/727,377

(22) Filed: Mar. 19, 2010

(51) Int. Cl. H01Q 1/38; H01L 21/56

(52) U.S. Cl. 343/700 MS; 438/124; 257/E21.502

(57) ABSTRACT

In described embodiments, a package inverted-F antenna is disclosed. The inverted-F antenna (IFA) is printed on a semiconductor package, and conductive bonding material is applied to leads of the IFA and terminal pads of a substrate when bonding the package to the substrate holding a semiconductor die. Wire leads couple the output terminals of the die to the terminal pads and, hence, the IFA.

### BACKGROUND OF THE INVENTION

1. Field of the Invention

The present invention relates to communications, and, in particular, to integrated radio antenna and circuit packages.

2. Description of the Related Art

Wireless communications are increasingly integrated into public applications. Radio solutions for such applications are varied, such as those specified in IEEE standards 802.11 (e.g., WiFi) local area networks, 802.15 personal area networks (e.g., Bluetooth®), and 802.16 wide area networks. In many cases, form factors for these radio solutions are increasingly required to occupy less space. In some cases, reducing the form factor for a radio solution proposes integration of the necessary antenna within the package, typically mounted on an opposite side of the substrate to which is attached the semiconductor die incorporating the necessary circuitry to drive the antenna. However, these solutions are complex, and expensive to manufacture.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one embodiment, the present invention is a an integrated radio antenna packaged integrated by mounting a die on a substrate, the substrate having a plurality of terminal pads coupled to the die and having radio circuitry; and encapsulating the die with a die package by bonding the die package to the substrate, the die package having a top and a side. An antenna is formed on the top of the die package; and at least one conductive lead is formed on the side of the die package. The at least one conductive lead formed on the side of the die package is coupled to a corresponding one of the plurality of terminal pads at a corresponding junction with a conductive adhesive, thereby coupling the antenna to radio circuitry of the die and fastening, at least in-part, the die package to the substrate.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows an external view of a package inverted-F antenna (PIFA) in accordance with an exemplary embodiment of the present invention;

FIG. 2 shows a cross-section view of the package inverted-F antenna (PIFA) in accordance with the exemplary embodiment of FIG. 1;

FIG. 3 shows an exemplary IFA antenna configuration as might be employed with exemplary embodiments of the present invention; and

FIG. 4 shows an exemplary polar chart plot of the antenna characteristics for the IFA antenna of FIG. 3.

### DETAILED DESCRIPTION

In exemplary embodiments of the present invention, a package inverted-F antenna (PIFA) is disclosed. The inverted-F antenna (IFA) is printed on a semiconductor package, and conductive bonding material is applied to leads of the printed IFA and terminal pads of a substrate when bonding the package to the substrate holding a semiconductor die. Wire leads couple the output terminals of antenna driver circuitry of the die to the terminal pads and, hence, the printed IFA. Since an antenna of a radio solution occupies considerable space, integrating the antenna radiating structure on the top surface of an integrated circuit (IC) die package reduces the footprint of a complete radio solution.

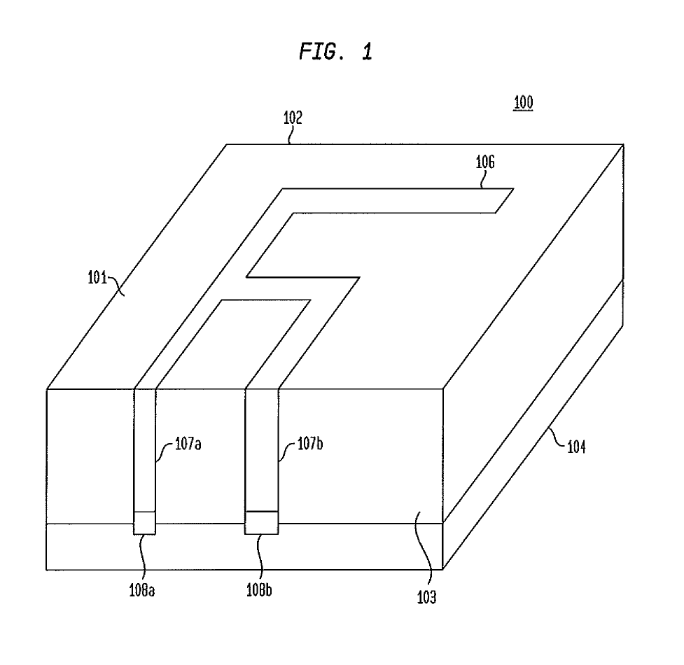

FIG. 1 shows an external view of a package inverted-F antenna (PIFA) 100 in accordance with an exemplary embodiment of the present invention. PIFA 100 comprises semiconductor die package 102 mounted upon substrate 104. Substrate 104 may provide a mounting base as well as conductor leads for a semiconductor die (not shown in FIG. 1). Provided upon the surface of package 102 is inverted-F antenna (IFA) 106, with radiating F-surface on top surface 101 of package 102 and conductive leads 107a and 107b formed on side surface 103 of package 102 coupled to corresponding legs of IFA 106. IFA 106 might be formed, for example, through printing or silk-screening with a conductive material on package 102, or by depositing a layer of the conductive material on package 102 and subsequently etching the surfaces of package 102 to firm IFA 106.

As shown in FIG. 1, in accordance with embodiments of the present invention, conductive adhesive is employed at junctions 108a and 108b in contact with i) leads 107a and 107b of IFA 106 and ii) substrate 104 when joining package 102 to substrate 104. Such conductive adhesive might be, for example, an epoxy compound with conductive material within the epoxy adhesive, and, as known in the art, other conductive adhesives might be employed. For example, in liquid crystal display panels, micro-spheres plated with conductive metal, such as gold, are suspended in a material between junctions so that, when pressure is applied to the surfaces to be bonded, the spheres are in contact to create a conductive path between the bonded surfaces. When joining package 102 to substrate 104, a non-conductive or other insulating bonding material is preferably employed around conductive leads 107a and 107b as to isolate conductive leads 107a and 107b from each other and from other external contact.

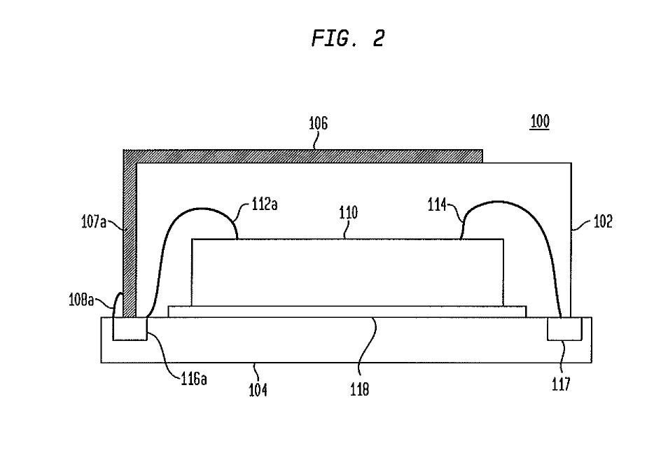

At junctions 108a and 108b, the conductive adhesive is also in contact with corresponding terminal pads (not shown in FIG. 1, but shown and described subsequently with respect to FIG. 2) mounted on or within substrate 104. Corresponding terminal pads are coupled, typically via gold or similar conductive wire, to the semiconductor die housed within package 102 and mounted on substrate 104.

FIG. 2 shows a cross-section view of PIFA 100 in accordance with an exemplary embodiment of FIG. 1. PIFA 100 comprises semiconductor die package 102 mounted upon substrate 104. Substrate 104 provides a mounting base 118 for semiconductor die 110 as well as conductor leads 112a and 114 (e.g., gold or similar conductive wire) coupling semiconductor die 110 to corresponding terminal pads 116a and 117. Although FIG. 2 only shows two terminal pads, such description is for illustration and, as known in the art, a typical semiconductor device might comprise many more terminal pads and corresponding conductor leads. Provided upon the surface of package 102 is IFA 106, with radiating F-surface on top surface 101 of package 102 and conductive leads 107a and 107b formed on side surface 103 of package 102 as described previously with respect to FIG. 1. In FIG. 2, only lead 107a is shown coupled to junction 108a and terminal pad 116a; the lead 107b is coupled to junction 108b and corresponding terminal pad 116b (not shown in FIG. 2).

In operation, semiconductor die 110 comprises circuitry to drive IFA 106 through leads 107a and 107b. Package 102 might be provided, either externally or internally, with material to provide a barrier to prevent radiation from IFA 106 from interfering with operation of circuits within semiconductor die 110.

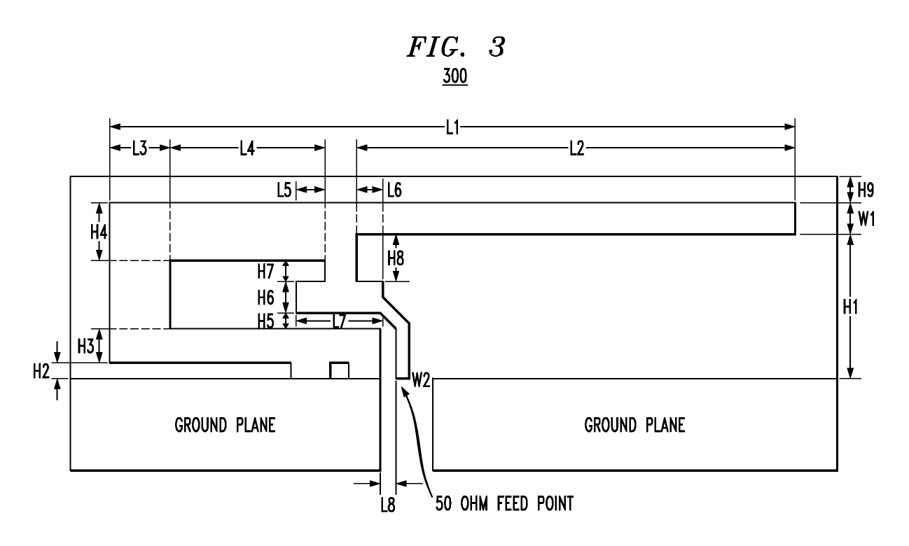

FIG. 3 shows an exemplary IFA antenna configuration 300 adapted from printed circuit board applications as might be employed with exemplary embodiments of the present invention. IFA antenna configuration 300 might be modified for operation in a given application and, as employed herein, illustrates that IFA antenna configuration 300 might be physically commensurate with dimensions of typically available semiconductor die packaging. Table 1 shows exemplary values for dimensions of the IFA antenna of FIG. 3, and from Table 1 the dimension H2 represents a height of conductive leads 107a and 107b, which are well within typical package thickness. Design techniques for planar IFAs are well known, such as described by Iulian Rosu, PIFA—Planar Inverted F Antenna, YO3DAC/VA3IUL www.qsl.net/va3iul.

TABLE 1

| | | | | |
|---|---|---|---|---|
| H1 | 5.70 mm | W2 | 0.45 | mm |
| H2 | 0.74 mm | L1 | 25.56 | mm |
| H3 | 1.29 mm | L2 | 16.40 | mm |
| H4 | 2.21 mm | L3 | 2.18 | mm |
| H5 | 0.66 mm | L4 | 4.80 | mm |
| H6 | 1.21 mm | L5 | 1.00 | mm |
| H7 | 0.80 mm | L6 | 1.00 | mm |
| H8 | 1.80 mm | L7 | 3.20 | mm |
| H9 | 0.61 mm | L8 | 0.45 | mm |
| W1 | 1.21 mm | | | |

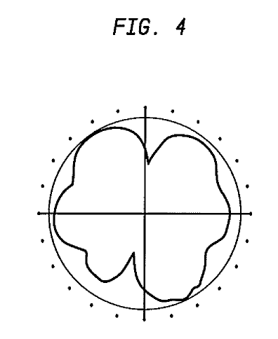

FIG. 4 shows an exemplary polar chart plot of the antenna characteristics for the IFA antenna of FIG. 3 for the XY vertical plane. As shown in FIG. 4, the IFA antenna of FIG. 3 is omni-directional, providing relatively even coverage of an area surrounding the package. Further information for such antenna configuration designed for a printed circuit board (PCB) application might be found in Auden Andersen, 2.4 GHz Inverted F Antenna, Design Note DN0007, Texas Instruments, 2007. Antenna field patterns for antenna configurations adapted for embodiments of the present invention will vary from those of PCBS, and one skilled in the art would tune of the dimensions of the antenna of FIG. 3 for use with a semiconductor package.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

While the exemplary embodiments of the present invention have been described with respect to processes of circuits, including possible implementation as a single integrated circuit, a multi-chip module, a single card, or a multi-card circuit pack, the present invention is not so limited. As would be apparent to one skilled in the art, various functions of circuit elements may also be implemented as processing blocks in a software program. Such software may be employed in, for example, a digital signal processor, micro-controller, or general purpose computer.

Unless explicitly stated otherwise, each numerical value and range should be interpreted as being approximate as if the word “about” or “approximately” preceded the value of the value or range. Also, signals and corresponding nodes or ports may be referred to by the same name and are interchangeable for purposes here.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

It will be further understood that various changes in the details, materials, and arrangements of the parts which have been described and illustrated in order to explain the nature of this invention may be made by those skilled in the art without departing from the scope of the invention as expressed in the following claims.

We claim:

1. Apparatus for radio communication, the apparatus comprising:
a die mounted on a substrate, the substrate having a plurality of terminal pads coupled to the die and having radio circuitry;
a die package, the die package having a top and a side and the die package coupled to the substrate so as to encapsulate the die; and
an antenna, the antenna formed on the top of the die package and coupled to at least one conductive lead formed on the side of the die package,
wherein the antenna is coupled to the radio circuitry of the die configured to drive the antenna by at least one conductive lead coupled to a corresponding one of the plurality of terminal pads at a corresponding junction with a conductive adhesive, the adhesive employed to, at least in-part, fasten the die package to the substrate.

2. The invention of claim 1, wherein the antenna is an inverted-F antenna.

3. The invention of claim 2, wherein the antenna is formed by at least one of a painting process, a printing process and a silk-screening process.

4. The invention of claim 2, wherein the antenna is formed by etching a layer of conductive material deposited upon the top and the side of the die package.

5. The invention of claim 2A, wherein the apparatus comprises two conductive leads formed on the side of the package coupling first and second legs of the inverted-F antenna to corresponding one of the terminal pads through the conductive adhesive bonding the die package to the substrate.

6. The invention of claim 1, wherein the package further comprises a layer configured to isolate the die from radiated energy from the antenna.

7. The invention of claim 1, wherein the apparatus comprises non-conductive adhesive between the die package and the substrate, and wherein at least a portion of the non-conductive adhesive is further positioned between one or more junctions having the conductive adhesive.

8. The invention of claim 1, wherein the radio circuitry is configured to operate in accordance with at least one of an IEEE 802.11, an IEEE 802.15, and an IEEE 802.16 standard.

9. A method of providing an integrated radio antenna packaged circuit, the method comprising the steps of:
mounting a die on a substrate, the substrate having a plurality of terminal pads coupled to the die and having radio circuitry;
encapsulating the die with a die package by bonding the die package to the substrate, the die package having a top and a side;
forming an antenna on the top of the die package;
forming at least one conductive lead on the side of the die package; and
coupling the at least one conductive lead formed on the side of the die package to a corresponding one of the plurality of terminal pads at a corresponding junction with a conductive adhesive, thereby coupling the antenna to radio circuitry of the die and fastening, at least in-part, the die package to the substrate.

10. The invention of claim 9, wherein forming the antenna includes forming an inverted-F antenna.

11. The invention of claim 10, wherein forming the antenna is by at least one of the steps of painting, printing and silk-screening material of the antenna on the top and the side of the die package.

12. The invention of claim 10, wherein forming the antenna is by i) depositing a layer of conductive material upon the top and the side of the die package and ii) etching the layer of conductive material to form the antenna.

13. The invention of claim 10, wherein the step of forming at least one conductive lead formed on the side of the die package comprises forming two conductive leads on the side of the package and coupling first and second legs of the inverted-F antenna to corresponding one of the terminal pads through the conductive adhesive, thereby bonding the die package to the substrate.

14. The invention of claim 9, wherein the package further comprises depositing an isolation layer on the die package and isolating, with the isolation layer, the die from radiated energy from the antenna.

15. The invention of claim 9, further comprising applying a non-conductive adhesive between the die package and the substrate, and positioning at least a portion of the non-conductive adhesive between one or more junctions having the conductive adhesive.

16. The invention of claim 9, further comprising operating the radio circuitry in accordance with at least one of an IEEE 802.11, an IEEE 802.15, and an IEEE 802.16 standard.
